(19) United States
(12) Patent Application Publication
(10) Pub. No.: US 2026/0157143 A1
(43) Pub. Date: Jun. 4, 2026

(54) FIXING ASSEMBLY AND SUBSTRATE CARRIER USING THE SAME

(71) Applicant: Gudeng Precision Industrial Co., LTD., New Taipei City (TW)

(72) Inventors: Ming-Chien Chiu, New Taipei City (TW); Chi-Lin Li, New Taipei City (TW); Chia-Ch Lin, New Taipei City (TW); Yung-Chin Pan, New Taipei City (TW); Chia-Liang Liu, New Taipei City (TW)

(21) Appl. No.: 19/393,400

(22) Filed: Nov. 18, 2025

Related U.S. Application Data
(60) Provisional application No. 63/727,043, filed on Dec. 2, 2024.

(51) Int. Cl. H01L 21/673; H01L 21/68

(52) U.S. Cl. CPC H10P 72/1922; H10P 72/1914; H10P 72/1918; H10P 72/50

(57) ABSTRACT

A fixing assembly and a substrate carrier using the same include a sleeve element and a pin element. The substrate carrier includes a shell, a base, a positioning element, and the fixing assembly. The shell has a bottom portion. The base is detachably assembled to the bottom portion and has a through hole. The positioning element is configured to be fixed onto the base and has a fixing hole aligned with a portion of the through hole. The fixing assembly is configured to fix the positioning element to the base. The sleeve element is configured to be inserted into the fixing hole and the through hole. The pin element is configured to be wedged into the sleeve element, thereby deforming the sleeve element so as to lock the sleeve element to the positioning element and the base.

### RELATED APPLICATIONS

This application claims priority to U.S. Provisional Patent Application No. 63/727,043, by CHIU, et al., titled “FIXING ASSEMBLY AND SUBSTRATE CARRIER USING THE SAME,” filed on Dec. 2, 2024, which is hereby incorporated by reference in their entirety.

### BACKGROUND OF THE INVENTION

### Technical Field

The present invention relates to a fixing assembly. More particularly, the present invention relates to a fixing assembly and a substrate carrier for use in the field of semiconductor technology.

### Description of Related Art

In the semiconductor industry, various types of substrates are widely used in processes related to the manufacture of semiconductor devices so that different semiconductor processes can be performed. Whether these substrates are used in the initial, intermediate, or post-fabrication processes, there is a need for transporting or moving the substrates between different work stations. In known applications, the substrates are accommodated in a substrate carrier to prevent collisions and contaminations from the external environment.

One known type of substrate carrier includes a carrier body and a base. The base is configured to fix to the shell of the carrier body, and the substrate carrier can be supported by an external equipment through the base. The base also helps the positioning of the substrate carrier at different work stations. In known application, in order to achieve precise positioning of the substrate carrier, one or more kinematic coupling (KC) components, such as V-shaped KC grooves, are provided on the base.

In one example, the substrate carrier is used to accommodate wafers. According to the Semiconductor Equipment and Materials International (SEMI) standards, three KC components are required to be provided on the base of the substrate carrier. When the substrate carrier is placed on a wafer load port equipment, the three KC components engage with three corresponding KC positioning pins on the load port equipment, to achieve precise positioning of the substrate carrier. However, after prolonged and repeated use, the KC components (for example, KC grooves) are susceptible to wear or damage, resulting in a decrease in positioning accuracy, and therefore must be replaced. Accordingly, the KC components are consumable parts.

In one known technical solution, the KC components and the base are integrally formed as a single piece. When the KC components need to be replaced, the entire base has to be replaced together, which significantly increases the maintenance cost.

In another known technical solution, the KC components are independent parts that are assembled and fastened onto the base by screws. However, this screw-fastening solution has the following disadvantages: (A) the assembly process is complicated and time-consuming, and requires the use of additional tools (such as a screwdriver); (B) the screws are prone to loosening, which may cause instability in the positioning of the KC components and adversely affect the overall assembly yield; and (C) metal screws increase the overall weight of the substrate carrier, thereby negatively affecting its transportability and automated handling performance.

Therefore, there exists a need in the industry for an improved fixing mechanism and a substrate carrier using the same, so as to overcome the aforementioned drawbacks of known technical solutions.

### SUMMARY

In view of the above-mentioned problems, the present invention is to provide a fixing assembly and a substrate carrier using the same. The fixing assembly includes a sleeve element and a pin element configured to be wedged into the sleeve element, thereby deforming the sleeve element to lock the sleeve element to a positioning element and a base of the substrate carrier. By using the fixing assembly, the need for screws and additional tools is eliminated, thereby simplifying the assembly process and thus improving the overall efficiency of the semiconductor fabrication.

According to one aspect of the invention, a fixing assembly adapted to be used in a substrate carrier is provided. The fixing assembly is configured to fix a positioning element to a base of the substrate carrier. The fixing assembly includes a sleeve element and a pin element. The sleeve element is configured to be inserted into a fixing hole of the positioning element and a through hole of the base. The pin element is configured to be wedged into the sleeve element, thereby deforming the sleeve element so as to lock the sleeve element to the positioning element and the base.

In one embodiment, the sleeve element includes a head portion and a hollow stem connected to the head portion. The head portion is larger in diameter than the hollow stem. The hollow stem is configured to be inserted into the fixing hole and the through hole, such that when the hollow stem is inserted into a locking position, the head portion abuts against the positioning element.

In one embodiment, the pin element includes a pin head and a pin stem connected to the pin head. The pin head is configured to be fitted into the head portion, and the pin stem is configured to be wedged into the hollow stem, thereby outwardly deforming the hollow stem so that the pin stem is received therein, thereby locking the sleeve element to the positioning element and the base.

According to another aspect of the invention, a substrate carrier is provided. The substrate carrier includes a shell, a base, a positioning element, and a fixing assembly. The shell has a bottom portion. The base is detachably assembled to the bottom portion and has a through hole. The positioning element is configured to be fixed onto the base and has a fixing hole aligned with a portion of the through hole. The fixing assembly is configured to fix the positioning element to the base, and the fixing assembly includes a sleeve element and a pin element. The sleeve element is configured to be inserted into the fixing hole and the through hole. The pin element is configured to be wedged into the sleeve element, thereby deforming the sleeve element so as to lock the sleeve element to the positioning element and the base.

In one embodiment, the sleeve element includes a head portion and a hollow stem connected to the head portion. The pin element includes a pin head and a pin stem connected to the pin head. The head portion is larger in diameter than the hollow stem. The hollow stem is configured to be inserted into the fixing hole and the through hole. The pin head is configured to be fitted into the head portion. The pin stem is configured to be wedged into the hollow stem, thereby outwardly deforming the hollow stem so that the pin stem is received therein, thereby locking the sleeve element to the positioning element and the base.

In another embodiment, the positioning element is a groove element configured to interact with a positioning pin of an external equipment, so as to position the substrate carrier on the external equipment.

In yet another embodiment, the base includes a first flange, and the bottom portion of the shell includes a second flange. The first flange and the second flange are configured to mate with each other so as to lock the base to the shell.

In a further embodiment, the first flange includes a first section and a second section that are separated from each other.

In one embodiment, the base includes a locking arm, and the bottom portion of the shell includes a locking pillar configured to engage with the locking arm.

In another embodiment, the locking arm has a locking aperture, and the locking pillar has an inclined surface. The locking arm is slidable along the inclined surface until the locking pillar is received in the locking aperture, thereby engaging the locking pillar with the locking arm.

The fixing assembly and the substrate carrier using the same according to the embodiments of the invention includes the sleeve element and the pin element. The pin element is configured to be inserted into the sleeve element, thereby deforming the sleeve element to lock the sleeve element to the positioning element and the base. The need for screws and additional tools is eliminated, thereby simplifying the assembly process and improving the overall efficiency of semiconductor fabrication. Another advantage of eliminating screws is that it prevents the generation of particles during screw fastening, thereby enhancing the overall cleanliness of the substrate carrier.

### BRIEF DESCRIPTION OF DRAWINGS

The present invention can be more fully understood by reading the following detailed description of the embodiment, with reference made to the accompanying drawings as follows.

FIG. 1 is a three-dimensional view of a substrate carrier according to one embodiment of the invention before assembly.

FIG. 2 is a three-dimensional view of the substrate carrier after assembly.

FIG. 3a is a three-dimensional view of a sleeve element and a pin element.

FIG. 3b is a three-dimensional view of the sleeve element and the pin element after assembly.

FIG. 4a is a schematic view of the base and the positioning element.

FIG. 4b is a schematic view of the sleeve element and the components of FIG. 4a after assembly.

FIG. 4c is a schematic view of the pin element and the components of FIG. 4b after assembly.

FIG. 4d is a schematic view of the components of FIG. 4c after assembly.

FIG. 5 is a schematic view of the shell and the base of FIG. 1.

FIG. 6a is a schematic view before the base and the shell are locked with each other.

FIG. 6b is a schematic view of the base and the shell during locking.

FIG. 6c is a schematic view after the base is moved a certain distance relative to the shell.

FIG. 6d is a schematic view after the base is moved a further distance relative to the shell.

FIG. 6e is a schematic view after the base and the shell are locked with each other.

### DETAILED DESCRIPTION

The technical features and the content of the invention will be described in detail below with reference to the accompanying drawings. The embodiments described herein are exemplary implementations of the present invention and are not intended to limit the scope of the invention. In fact, the invention may be practiced in various forms, and the scope of the invention should not be construed as being limited thereto. The descriptions of embodiments are provided to make the technical features of the invention more explicit and complete and to fully disclose the invention so that those skilled in the art may implement it accordingly. In the detailed description of the embodiments, identical reference numerals refer to identical or similar elements. As used herein, unless otherwise clearly indicated by the context, the singular forms “a,” “an,” and “the” are intended to include their respective plural forms as well. Furthermore, when the terms “comprise,” “include,” or “have” are used in the specification, they do not preclude the presence or addition of one or more other features, steps, elements, components, and/or groups thereof.

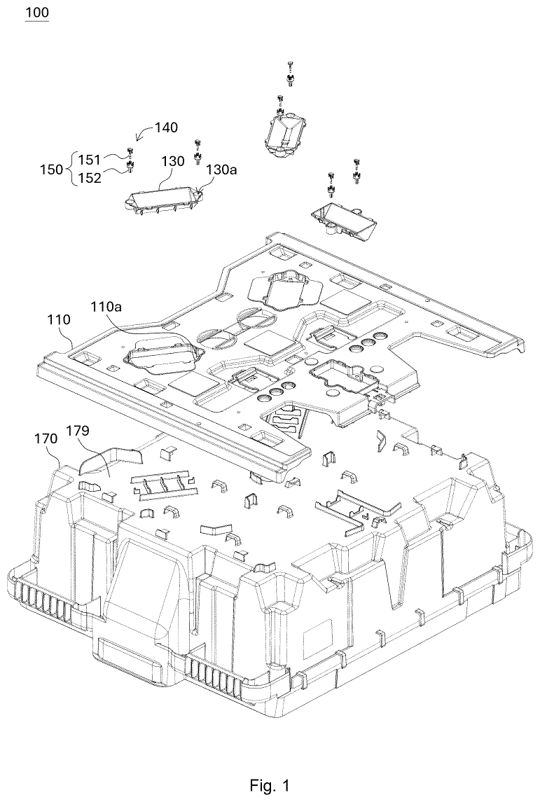

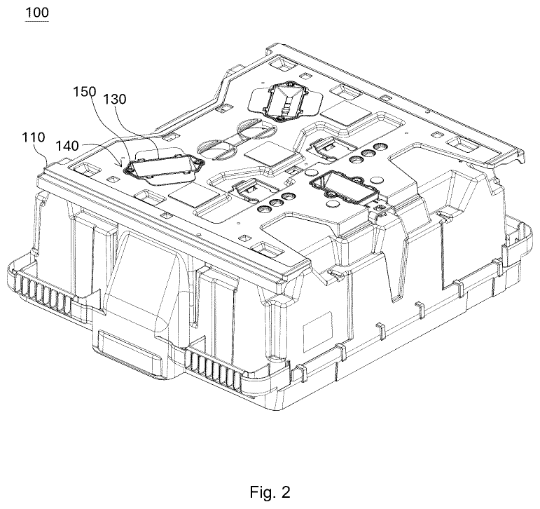

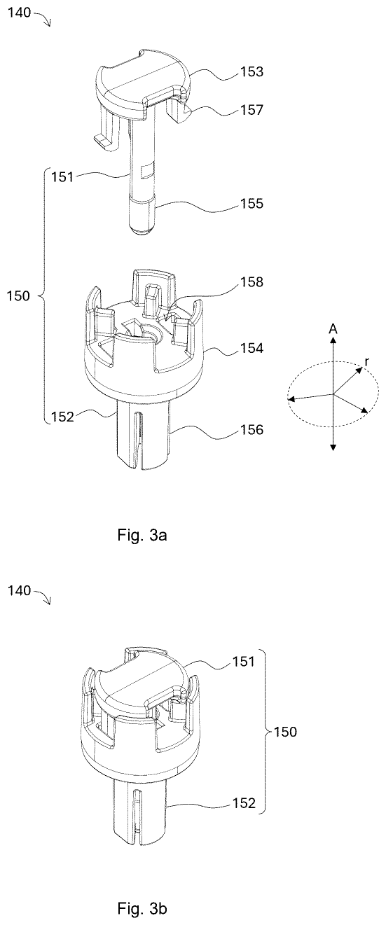

Please refer to FIG. 1 to FIG. 3b. FIG. 1 is a three-dimensional view of a substrate carrier according to one embodiment of the invention before assembly. FIG. 2 is a three-dimensional view of the substrate carrier after assembly. FIG. 3a is a three-dimensional view of a sleeve element and a pin element. FIG. 3b is a three-dimensional view of the sleeve element and the pin element after assembly. In the present embodiment, the substrate carrier 100 includes a shell 170, a base 110, a positioning element 130, and a fixing assembly 140. The shell 170 has a bottom portion 179, and the base 110 is detachably assembled to the bottom portion 179. The base 110 has a through hole 110a. The positioning element 130 is configured to be fixed onto the base 110 and has a fixing hole 130a aligned with a portion of the through hole 110a. The number of the fixing holes 130a may be one or more, and the number of the through holes 110a may also be one or more. Whether the numbers of the fixing holes 130a and the through holes 110a are the same or different, as long as the fixing holes 130a are aligned and communicate with a portion of the through holes 110a, such configurations fall within the scope of the invention. For example, in a case where two fixing holes 130a and three through holes 110a are provided, the two fixing holes 130a are aligned with two (of the three) through holes 110a respectively. The fixing assembly 140 is configured to fix the positioning element 130 to the base 110. The fixing assembly 140 includes a sleeve element 152 and pin element 151. The sleeve element 152 is configured to be inserted into the fixing hole 130a and the through hole 110a. The pin element 151 is configured to be wedged into the sleeve element 152, thereby deforming the sleeve element 152 so as to lock the sleeve element 152 to the positioning element 130 and the base 110.

In the present embodiment, the sleeve element 152 includes a head portion 154 and a hollow stem 156 connected to the head portion 154, the head portion 154 being larger in diameter than the hollow stem 156. The hollow stem 156 is configured to be inserted into the fixing hole 130a and the through hole 110a. When the hollow stem 156 is inserted into a first locking position, the head portion 154 abuts against the positioning element 130. In addition, the pin element 151 of the present embodiment includes a pin head 153 and a pin stem 155 connected to the pin head 153. The pin head 153 is configured to be fitted into the head portion 154, and the pin stem 155 is configured to be wedged into the hollow stem 156, thereby outwardly deforming the hollow stem 156 so that the pin stem 155 is received therein, thereby locking the sleeve element 152 to the positioning element 130 and the base 110. In this manner, the fixing assembly 140 is configured as a push-lock mechanism 150.

Furthermore, the pin element 151 further includes a locking hook 157, and the sleeve element 152 further includes a locking hole 158. Exemplarily, the pin element 151 is inserted into the sleeve element 152 in an axial direction A. When the pin element 151 is wedged to a second locking position, the locking hook 157 engages with the locking hole 158, thereby securing the pin head 153 to the head portion 154. At this time, the pin stem 155, which is wedged into the hollow stem 156, pushes the hollow stem 156 outwardly in a radial direction r, causing the hollow stem 156 to expand outwardly and to engage tightly with the through hole 110a and the fixing hole 130a.

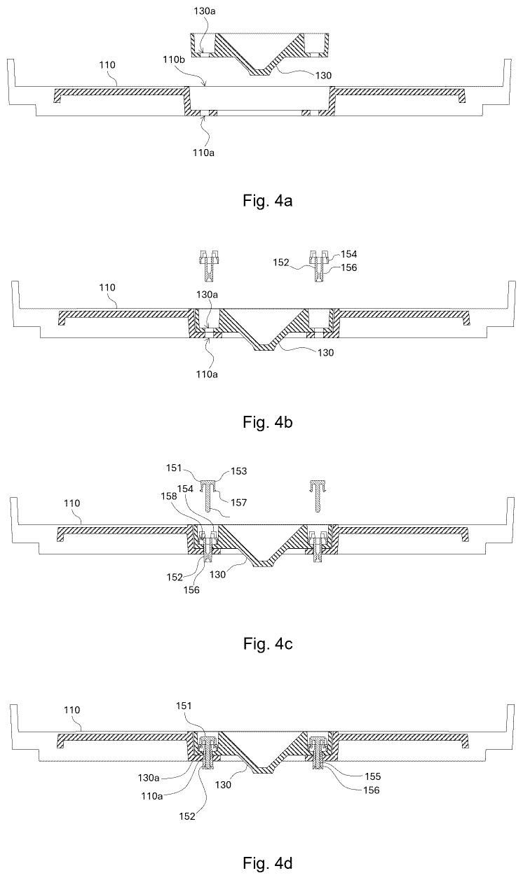

The locking mechanism between the sleeve element 152, the positioning element 130, and the base 110 will be described in detail below. Please refer to FIGS. 4a to 4d. FIG. 4a is a schematic view of the base 110 and the positioning element 130. FIG. 4b is a schematic view of the sleeve element and the components in FIG. 4a after assembly. FIG. 4c is a schematic view of the pin element and the components in FIG. 4b after assembly. FIG. 4d is a schematic view of the components in FIG. 4c after assembly.

First, as shown in FIG. 4a, the base 110 is provided with an accommodating space 110b corresponding to the positioning element 130 and being configured to receive the positioning element 130. During assembly, the positioning element 130 is first aligned with the accommodating space 110b and then moved downward into the accommodating space 110b.

As shown in FIG. 4b, after the positioning element 130 is received in the accommodating space 110b, the through hole 110a of the base 110 is aligned with the fixing hole 130a of the positioning element 130, such that the hollow stem 156 of the sleeve element 152 can pass therethrough. When the sleeve element 152 is inserted downward through the fixing hole 130a and the through hole 110a to the fist locking position, the head portion 154 abuts against a surface of the positioning element 130 since the head portion 154 of the sleeve element 152 is larger in diameter than the hollow stem 156.

As shown in FIG. 4c, when the sleeve element 152 is inserted to the first locking position, the base 110, the positioning element 130, and the head portion 154 of the sleeve element 152 are sequentially stacked. Next, the pin element 151 is inserted into the sleeve element 152. When the pin element 151 is inserted to the second locking position, the pin head 153 is fitted and secured to the head portion 154. In the present embodiment, the pin head 153 is fitted and secured to the head portion 154 through the locking hook 157 of the pin element 151 being engaged with the locking hole 158 of the sleeve element 152.

As shown in FIG. 4d, when the pin element 151 is wedged into the sleeve element 152, the pin stem 155 is wedged into the inner side of the hollow stem 156 and pushes the hollow stem 156 outwardly from the inside, thereby deforming the hollow stem 156 so that the pin stem 155 is received therein. The technical solution used in the present embodiment causes the hollow stem 156 to expand outward and firmly engage with the fixing hole 130a and the through hole 110a, thereby locking the sleeve element 152 with the positioning element 130 and the base 110. According to the foregoing locking mechanism, the fixing assembly 140 is configured to function as the push-lock mechanism 150, achieving a convenient push-lock effect.

In the present embodiment, the positioning element 130, for example, is a groove element. When the positioning element 130 and the base 110 are fixed together, the positioning element 130 is configured to interact with a positioning pin of an external equipment so as to position the substrate carrier 100 on the external equipment. In one embodiment, when the substrate carrier 100 is used for carrying wafers, the external equipment may be a wafer load port device having a door opening/closing mechanism. The technical features of the external equipment and its positioning pins are not limited in the present invention. In addition, the fixing assembly 140 and the substrate carrier 100 using the same of the present invention are not limited to being used with wafer load port devices. Any other external equipment that requires positional alignment with the positioning element 130 of the substrate carrier 100 is applicable to the present invention.

In the fixing assembly and the substrate carrier using the same according to the embodiments of the present invention, the pin element is wedged into the sleeve element, allowing the fixing assembly to conveniently, rapidly, and securely fix the positioning element to the base without the need for screws or additional tools. This use of the fixing assembly simplifies the assembly process and improves assembly efficiency, thereby enhancing the overall efficiency of semiconductor fabrication. Another advantage of not using screws is that it prevents the generation of particles during fastening, which is beneficial to the overall cleanliness of the substrate carrier.

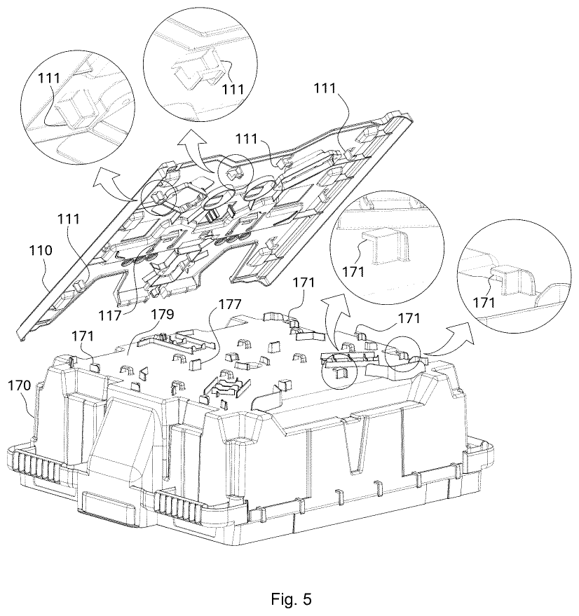

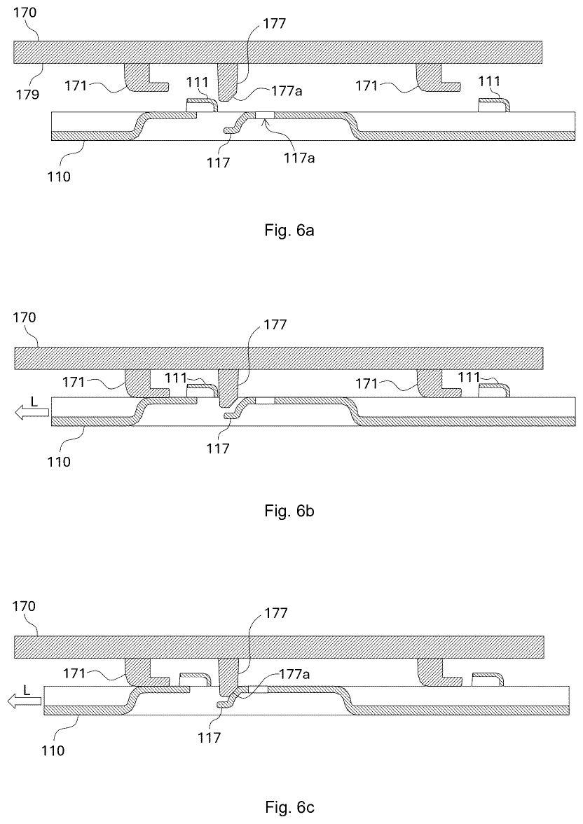

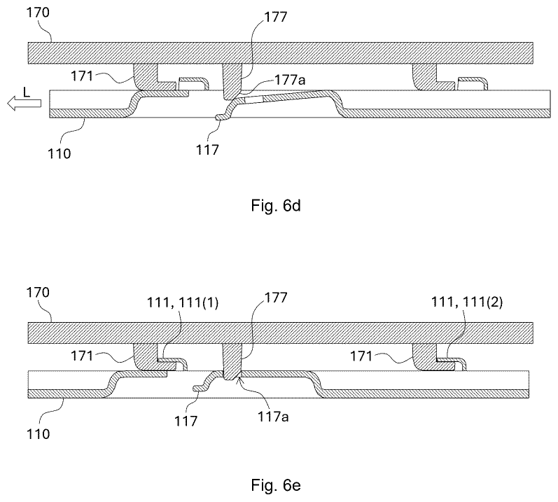

Please continue to refer to FIG. 1. As previously described, the substrate carrier 100 of the present embodiment includes the shell 170. The technical solution for locking the base 110 to the shell 170 in the embodiments of the present invention will be elaborated below. Please refer to FIG. 5 and FIGS. 6a to 6e. FIG. 5 is a schematic view of the shell and the base of FIG. 1. FIG. 6a is a schematic view before the base and the shell are locked with each other. FIG. 6b is a schematic view of the base and the shell during locking. FIG. 6c is a schematic view after the base is moved a certain distance relative to the shell. FIG. 6d is a schematic view after the base is moved a further distance relative to the shell. FIG. 6e is a schematic view after the base and the shell are locked with each other.

Please refer to FIG. 5 and FIG. 6a together. In the present embodiment, the base 110 includes a first flange 111 and the bottom portion 179 of the shell 170 includes a second flange 171. The first flange 111 and the second flange 171 are configured to mate with each other so as to lock the base 110 to the shell 170. In addition, the base 110 further includes a locking arm 117, and the bottom portion 179 of the shell 170 further includes a locking pillar 177 configured to engage with the locking arm 117. Furthermore, the locking arm 117 has a locking aperture 117a, and the locking pillar 177 has an inclined surface 177a. The locking arm 117 is slidable along the inclined surface 177a until the locking pillar 177 is received in the locking aperture 117a, thereby engaging the locking arm 117 with the locking pillar 177.

Please refer to FIG. 6a. During the locking process of the base 110, the base 110 is generally aligned with the shell 170 so that the first flange 111 is positioned adjacent to the second flange 117. Then the base 110 is moved toward the shell 170 until at least one of the first flange 111 and the second flange 117 comes into contact with the surface of the shell 170 or the base 110. In the present embodiment, it is the second flange 171 that comes into contact with the surface of the base 110, as shown in FIG. 6b.

As shown in FIG. 6b, after the base 110 is in contact with the shell 170, the base 110 is then moved in a locking direction L relative to the shell 170.

As shown in FIG. 6c, after the base 110 is moved a certain distance in the locking direction L, the locking arm 117 cones into contact with the inclined surface 177a of the locking pillar 177. The base 110 is then further moved.

As shown in FIG. 6d, as the base 110 continues to move in the locking direction L relative to the shell 170, the locking arm 117 slides along the inclined surface 177a and is lifted by the locking pillar 177. The base 110 is then further moved.

As shown in FIG. 6e, the base 110 continues to move in the locking direction L relative to the shell 170 until the locking pillar 177 is received in the locking aperture 117a of the locking arm 117. At this point, the locking arm 117 engages and locks the locking pillar 177, and the second flange 171 is inserted into the first flange 111 to be mated therewith. In this manner, the base 110 and the shell 170 are conveniently, rapidly, and securely locked with each other.

On the other hand, to remove the base 110 from the shell 170, the locking arm 117 needs to be pulled so that the locking pillar 177 is released from the locking aperture 117a. Then, by moving the base 110 in the direction opposite to the locking direction L, the base 110 can be easily detached from the shell 170.

Moreover, in the present embodiment, the first flange 111 on the base 110 includes a first section 111(1) and a second section 111(2) that are separated from each other and located on two opposite sides of the locking arm 117. As shown in FIG. 6e, the first flange 111 on the left side is defined as the first section 111(1), and the first flange 111 on the right side is defined as the second section 111(2). This multi-section configuration of the first flange 111 enhances the stability of locking between the base 110 and the shell 170. Correspondingly, the second flange 171 on the shell 170 also includes two separate sections, which respectively mate with the first section 111(1) and the second section 111(2) of the first flange 111. However, the embodiments of the invention are not limited thereto. The first flange 111 and the second flange 171 may respectively include three or more sections, which mate with each other correspondingly to provide an even more stable locking effect. The shape and structures of the first flange 111 and the second flange 171 are not limited to those shown in FIG. 5 and FIGS. 6a to 6e. Any other mechanical designs that can achieve mutual interlocking, inter-engagement, or coupling may also be applied to the present invention.

According to another aspect of the invention, a fixing assembly is provided. In one embodiment, the fixing assembly is adapted to be used in a substrate carrier and is configured to fix a positioning element to a base of the substrate carrier. The fixing assembly includes a sleeve element and a pin element. The sleeve element is configured to be inserted into a fixing hole of the positioning element and a through hole of the base. The pin element is configured to be wedged into the sleeve element, thereby deforming the sleeve element to lock the sleeve element to the positioning element and the base. The technical features of the fixing assembly described in the present embodiment are the same as those of the fixing assembly 140 of the substrate carrier 100 in the foregoing embodiments in relation to FIG. 1 to FIG. 6e, and thus will not be repeated here.

The fixing assembly and the substrate carrier using the same according to the embodiments of the invention include the sleeve element and the pin element. The pin element is wedged into the sleeve element, thereby deforming the sleeve element, so as to lock the sleeve element to the positioning element and the base. The need for screws and additional tools is eliminated, thereby simplifying the assembly process and improving the overall efficiency of semiconductor fabrication. Another advantage of eliminating screws is that it prevents the generation of particles during screw fastening, thereby enhancing the overall cleanliness of the substrate carrier.

Although the present invention has been disclosed with a number of embodiments as above, they are not intended to limit the present invention. Any person skilled in the art can make various modifications and refinements without departing from the spirit and scope of the present invention. Therefore, the protection scope of the present invention shall be defined by the scope of the appended claims.

What is claimed is:

1. A fixing assembly adapted to be used in a substrate carrier, the fixing assembly being configured to fix a positioning element to a base of the substrate carrier, the fixing assembly comprising:
a sleeve element configured to be inserted into a fixing hole of the positioning element and a through hole of the base; and
a pin element configured to be wedged into the sleeve element, thereby deforming the sleeve element to lock the sleeve element to the positioning element and the base.

2. The fixing assembly according to claim 1, wherein the sleeve element comprises a head portion and a hollow stem connected to the head portion, the head portion being larger in diameter than the hollow stem, the hollow stem being configured to be inserted into the fixing hole and the through hole, such that when the hollow stem is inserted into a locking position, the head portion abuts against the positioning element.

3. The fixing assembly according to claim 2, wherein the pin element comprises a pin head and a pin stem connected to the pin head, the pin head being configured to be fitted into the head portion, and the pin stem being configured to be wedged into the hollow stem, thereby outwardly deforming the hollow stem so that the pin stem is received therein, thereby locking the sleeve element to the positioning element and the base.

4. A substrate carrier, comprising:
a shell having a bottom portion;
a base detachably assembled to the bottom portion and having a through hole;
a positioning element configured to be fixed onto the base and having a fixing hole aligned with a portion of the through hole; and
a fixing assembly configured to fix the positioning element to the base, the fixing assembly comprising:
a sleeve element configured to be inserted into the fixing hole and the through hole; and
a pin element configured to be wedged into the sleeve element, thereby deforming the sleeve element so as to lock the sleeve element to the positioning element and the base.

5. The substrate carrier according to claim 4, wherein the sleeve element comprises a head portion and a hollow stem connected to the head portion, and the pin element comprises a pin head and a pin stem connected to the pin head, the head portion being larger in diameter than the hollow stem, the hollow stem being configured to be inserted into the fixing hole and the through hole, the pin head being configured to be fitted into the head portion, the pin stem being configured to be wedged into the hollow stem, thereby outwardly deforming the hollow stem so that the pin stem is received therein, thereby locking the sleeve element to the positioning element and the base.

6. The substrate carrier according to claim 4, wherein the positioning element is a groove element configured to interact with a positioning pin of an external equipment, so as to position the substrate carrier on the external equipment.

7. The substrate carrier according to claim 4, wherein the base comprises a first flange and the bottom portion of the shell comprises a second flange, the first flange and the second flange being configured to mate with each other so as to lock the base to the shell.

8. The substrate carrier according to claim 7, wherein the first flange comprises a first section and a second section that are separated from each other.

9. The substrate carrier according to claim 4, wherein the base comprises a locking arm, and the bottom portion of the shell comprises a locking pillar configured to engage with the locking arm.

10. The substrate carrier according to claim 9, wherein the locking arm has a locking aperture, and the locking pillar has an inclined surface, the locking arm being slidable along the inclined surface until the locking pillar is received in the locking aperture, thereby engaging the locking arm with the locking pillar.
